(19) United States
(12) Patent Application Publication
(10) Pub. No.: US 2026/0081118 A1
(43) Pub. Date: Mar. 19, 2026

(54) VARIABLE CONDUCTANCE EDGE RING FOR VAPOR DEPOSITION CHAMBER

(71) Applicant: Applied Materials, Inc., Santa Clara, CA (US)

(72) Inventors: Azhar ALI M.A, Bangalore (IN); Dhritiman Subha Kashyap, Bangalore (IN); Muhannad Mustafa, Milpitas, CA (US); Aditya Chuttar, Sunnyvale, CA (US)

(73) Assignee: Applied Materials, Inc., Santa Clara, CA (US)

(21) Appl. No.: 18/888,692

(22) Filed: Sep. 18, 2024

(51) Int. Cl. H01J 37/32

(52) U.S. Cl. CPC H01J 37/32642; H01J 37/32357; H01J 37/3244; H01J 2237/332

(57) ABSTRACT

Substrate processing chamber gas distribution assemblies and methods utilizing of processing substrates using the same are described. The gas distribution assembly includes an edge ring having a lower surface configured to be supported on a substrate processing chamber pedestal and an upper surface, the lower surface and the upper surface defining an edge ring thickness, the substrate processing chamber edge ring having a first edge ring thickness at a first edge of the ring-shaped body that is greater than a second edge ring thickness at a second edge opposite the first edge of the substrate processing chamber edge ring.

### TECHNICAL FIELD

Embodiments of the present disclosure pertain to the field of electronic device manufacturing. In particular, embodiments of the disclosure are directed to substrate processing chambers including variable conductance edge ring configured to control flow conductance of gas through a pumping liner of a substrate processing chamber.

### BACKGROUND

Microelectronic device manufacture includes the deposition of thin films of material in substrate processing chambers configured to performing various deposition, etch, and thermal processes, among other processes, upon substrates, such as silicon (Si) wafers, gallium arsenide (GaAs) wafers, glass, sapphire, and the like. Various etch processes and deposition processes, including chemical vapor deposition (CVD) and atomic layer deposition (ALD), can be optimized by controlling the process conditions within the substrate processing chamber. In particular, during a deposition process, the chemical reaction rate is impacted by processing chamber pressure as gas flow. As such, the ability to transition between and maintain precise target pressures within the substrate processing chamber is important to forming uniform deposition of thin films during semiconductor device fabrication.

Vapor deposition chambers, such as ALD chambers, designed with one-sided pumping have higher velocities near the pump and lower velocities away from the pump, impacting the flow uniformity in the process cavity and around the substrate upon which a film is deposited. However, the flow nonuniformity in the cavity should be minimized to achieve a better control deposition of film material on the substrate.

With one-sided pumping in vapor deposition chambers, variable conductance flow paths and liner holes are usually designed to attain better flow uniformity in the process cavity. However, existing edge ring designs tend to increase the surface area of the components, thus adding to the purge load. Accordingly, there is a need in the art for to provide further improvements in flow conductance of gas in vapor deposition substrate processing chambers.

### SUMMARY

A first aspect of the disclosure pertains to a substrate processing chamber edge ring comprising a ring-shaped body having a lower surface configured to be supported on a substrate processing chamber pedestal and an upper surface, the lower surface and the upper surface defining an edge ring thickness, the substrate processing chamber edge ring having a first edge ring thickness at a first edge of the ring-shaped body that is greater than a second edge ring thickness at a second edge opposite the first edge of the substrate processing chamber edge ring.

Another aspect of the disclosure pertains to substrate processing chamber gas distribution assembly comprising the substrate processing chamber edge ring described herein and a gas distribution faceplate having a top surface and a bottom surface, wherein the gas distribution faceplate is disposed above the substrate processing chamber edge ring and wedge-shaped profile of the substrate processing chamber edge ring provides a gap between the substrate processing chamber edge ring and the bottom surface of the gas distribution first plate that tapers from a first end of the gas distribution faceplate to a second end of the gas distribution faceplate such that the gap is larger on the first end than on the second end of the gas distribution faceplate.

Another aspect of the disclosure pertains to method of forming a film on a substrate in substrate processing chamber, the method comprising establishing a gas flow between a sloped edge ring surrounding a pedestal configured to support the substrate during a vapor deposition process, the substrate processing chamber edge ring having sloped profile configured to provide a sloped gap between the substrate processing chamber edge ring and a gas distribution faceplate disposed above the substrate processing chamber edge ring, wherein the sloped gap is less on a first end of the substrate processing chamber than on a second end of substrate processing chamber.

### BRIEF DESCRIPTION OF THE DRAWINGS

FIG. 1 is a schematic view of a substrate processing chamber configured for vapor deposition processes;

FIG. 2 is a schematic view of a substrate processing chamber gas distribution assembly used in the substrate processing chamber shown in FIG. 1 including an edge ring according to the prior art;

FIG. 3 is a partial view of the pumping side or end and slit valve side or end of a substrate processing chamber gas distribution assembly used in the substrate processing chamber shown in FIG. 1 according to an embodiment of the disclosure;

FIG. 4 is an isometric view of a substrate processing chamber edge ring according to an embodiment of the disclosure; and

FIG. 5 is a cross-sectional view taken along line 5-5 of FIG. 4.

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

According to one or more embodiments, when an element or structure is referred to as being “configured to” perform a particular function, or “made to” or “designed to” perform that function, however, when the Specification makes clear that the recited structure is “designed to” or “constructed to” perform that function, the element or structure is designed, made or configured to accomplish the specific objective.

Some embodiments of the present disclosure provide apparatus and methods that may be used to form film in substrate processing chambers, such as chemical vapor deposition (CVD) chamber, and to deposit materials during, for example, an CVD process. Some embodiments of the present disclosure provide apparatus and methods that may be used to form film in substrate processing chambers, such as an atomic layer deposition (ALD) chamber, and to deposit materials during, for example, an ALD process. Embodiments include substrate processing chambers and gas delivery systems which may include a remote plasma source and a gas distribution faceplate. The following substrate processing chamber description is provided for context and exemplary purposes, and should not be interpreted or construed as limiting the scope of the disclosure.

One or more embodiments of the present disclosure provide a variable conductance edge ring, the edge ring having circumferential variation in conductance through an angled profile. In one or more embodiments, the edge ring provides improved the gas flow conductance in the process cavity and around substrate when one-sided pumping is employed in a vapor deposition process in a substrate processing chamber by circumferentially varying flow conductance.

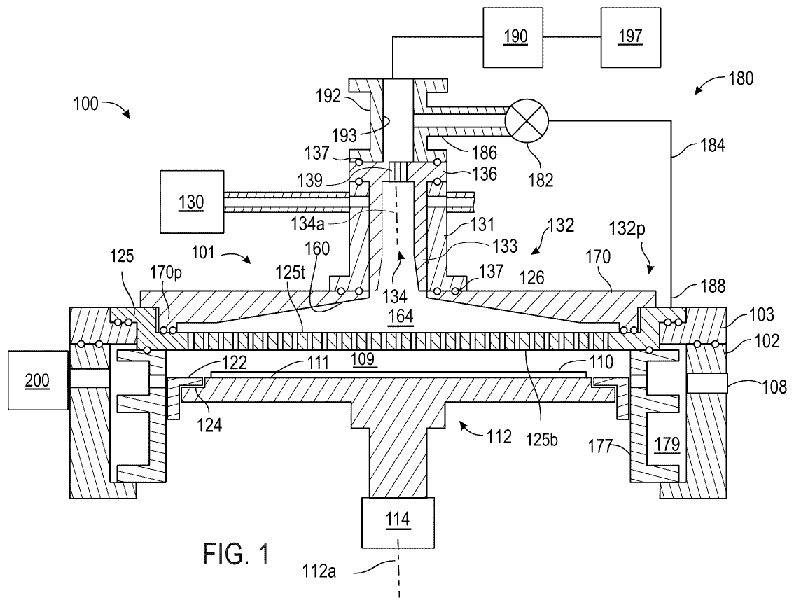

FIG. 1 is a schematic view of a substrate processing chamber 100 including a gas delivery system 130 configured for delivery of process gases to the substrate processing chamber 100 during CVD or ALD processes in accordance with one or more embodiments of the present disclosure. The substrate processing chamber 100 includes a chamber body 102 and a top wall 103 defining a processing volume 109 within the chamber body 102 and disposed below a chamber lid assembly 132. A slit valve 108 on one side or end in the chamber body 102 provides access for a robot (not shown) to deliver and retrieve a substrate 110, such as a 200 mm or 300 mm semiconductor wafer or a glass substrate, to and from the processing volume 109 of the substrate processing chamber 100. A chamber liner 177 is disposed between the processing volume 109 and the chamber body 102 of the substrate processing chamber 100 to protect the chamber from corrosive gases used during processing/cleaning.

A pedestal 112 supports the substrate 110 on a substrate receiving surface 111 in the substrate processing chamber 100. In some embodiments, the pedestal 112 is rotatable and the pedestal is rotated by a rotating motor 114 configured to rotate the pedestal 112 and the substrate 110 disposed on the pedestal 112. In some embodiments, the substrate processing chamber comprises a lift motor (not shown), a lift plate (not shown), connected to the lift motor, which are mounted in the substrate processing chamber 100 and configured to raise and lower lift pins (not shown) movably disposed through the pedestal 112. The lift pins raise and lower the substrate 110 over the surface of the pedestal 112. The pedestal 112 may include a vacuum chuck (not shown), an electrostatic chuck (not shown), or a clamp ring (not shown) configured to hold the substrate 110 on the pedestal 112 during a CVD or ALD deposition process used to form a film on the substrate.

The temperature of the pedestal 112 may be adjusted to control the temperature of the substrate 110. For example, the pedestal 112 may be heated using an embedded heating element, such as a resistive heater (not shown), or may be heated using radiant heat, such as heating lamps (not shown) disposed above the pedestal 112. A purge ring 122 may be disposed on the pedestal 112 to define a purge channel 124, which provides a purge gas to a peripheral portion of the substrate 110 to prevent deposition on the peripheral portion of the substrate 110.

The gas delivery system 130 is positioned above the chamber body 102 and configured to supply a gas, such as a process gas and/or a purge gas, to the substrate processing chamber 100. A vacuum system (not shown) is in communication with a pumping liner 179 to evacuate gases from the substrate processing chamber 100 and to help maintain a target pressure or pressure range inside the substrate processing chamber 100.

In some embodiments, the substrate processing chamber comprises a substrate processing chamber gas distribution assembly 201, which includes a chamber lid assembly 132. The chamber lid assembly 132 includes an inner gas channel 134 defined by a gas insert 133 extending through a central portion of the chamber lid assembly 132. As shown in FIG. 1, the inner gas channel 134 extends perpendicularly toward the substrate receiving surface 111 of the pedestal 112 and also extends along a central axis 134a of the inner gas channel 134, through backing plate 170, and to a contoured bottom surface 160 of the backing plate 170. The central axis of the inner gas channel is aligned with the central axis 112a of the pedestal 112 upon which the substrate 110 is centered during an ALD or CVD process. In some embodiments, an upper portion of the inner gas channel 134 is substantially cylindrical along central axis 134a and a lower portion of the inner gas channel 134 tapers away from the central axis 134a. The bottom surface 160 is sized and shaped to substantially cover the substrate 110 disposed on the substrate receiving surface 111 of the pedestal 112. The bottom surface 160 tapers from an outer edge of the backing plate 170 towards the inner gas channel 134. The gas delivery system 130 is configured to supply one or more gasses to the inner gas channel 134 during processing of the substrate 110 during a CVD or ALD process. In some embodiments, the gas delivery system 130 is coupled to the inner gas channel 134 via a single gas inlet. In some embodiments not shown, the gas delivery system 130 is coupled to the inner gas channel 134 via a plurality of gas inlets configured to supply different process gases, a purge gas, and other gases used during a CVD or ALD process.

A portion of bottom surface 160 of chamber lid assembly 132 may be contoured or angled downwardly and outwardly from a central opening coupled to the inner gas channel 134 to a peripheral portion 132p of chamber lid assembly 132 to help provide an improved velocity profile of a gas flow from inner gas channel 134 across the surface of substrate 110 (i.e., from the center of the substrate to the edge of the substrate). Bottom surface 160 may contain one or more surfaces, such as a straight surface, a concave surface, a convex surface, or combinations thereof. In one embodiment, bottom surface 160 is convexly funnel-shaped.

In one example, bottom surface 160 is downwardly and outwardly sloping toward an edge of the substrate receiving surface 111 to help reduce the variation in the velocity of the process gases traveling between bottom surface 160 of chamber lid assembly 132 and substrate 110 while assisting to provide uniform exposure of the surface of substrate 110 to a reactant gas. The components and parts of chamber lid assembly 132 may contain materials such as stainless steel, aluminum, nickel-plated aluminum, nickel, alloys thereof, or other suitable materials. In one embodiment, backing plate 170 may be independently fabricated, machined, forged, or otherwise made from a metal, such as aluminum, an aluminum alloy, steel, stainless steel, alloys thereof, or combinations thereof.

In some embodiments, the inner gas channel 134 and bottom surface 160 of the chamber lid assembly 132 may contain a mirror polished surface to help a flow of a gas along inner gas channel 134 and bottom surface 160 of chamber lid assembly 132.

The upper portion of the inner gas channel 134 is defined by the gas insert 133 disposed in an inner region of a gas manifold 131. The gas insert 133 includes a cap 136 at an upper portion of the gas insert 133 and a central passageway that at least partially defines the inner gas channel 134 of the gas manifold 131. The cap 136 extends over the gas manifold 131 to hold the gas insert 133 in place. The gas insert 133 and the cap 136 include a plurality of o-rings 137 disposed between the gas insert 133 and the gas manifold 131 to ensure proper sealing. In some embodiments, the gas insert 133 includes a plurality of circumferential apertures (nots shown) which, when the gas insert 133 is inserted into the gas manifold 131, form a corresponding plurality of circumferential channels (not shown). The plurality of circumferential channels are fluidly coupled to the inner gas channel 134 via a corresponding plurality of cap openings in the cap 136. In some embodiments, the gas distribution faceplate 125 is formed of a non-corrosive ceramic material such as, for example, aluminum oxide or aluminum nitride.

In some embodiments, the substrate processing chamber includes a remote plasma source (RPS) 190, an isolation collar 192 coupled to the RPS 190 at one end and the cap 136 at an opposite end, and a heater plate (not shown) coupled to an upper surface of the backing plate 170 circumferentially surrounding the gas manifold 131. The heater plate may be formed of stainless steel and include a plurality of resistive heating elements dispersed throughout the plate. A cleaning gas (i.e., purge gas) source 197 is fluidly coupled to the RPS 190. The cleaning gas source may include any gas suitable for forming a plasma to clean the substrate processing chamber 100. In some embodiments, for example, the cleaning gas may be nitrogen trifluoride (NF₃). The isolation collar 192 includes an inner channel 193 that is fluidly coupled to the inner gas channel 134 to flow a plasma from the RPS 190 through the inner gas channel 134 and into a reaction zone 164 above the gas distribution faceplate 125.

Typically, a cleaning gas is flowed through the inner gas channel 134 and the reaction zone 164 after a first gas is provided to the inner gas channel 134 by the gas delivery system 130 to quickly purge the first gas from the inner gas channel 134 and the reaction zone 164. Subsequently, a second gas is provided by the gas delivery system 130 to the inner gas channel 134 and the cleaning gas is again flowed through the inner gas channel 134 to the reaction zone 164 to quickly purge the second gas from the inner gas channel 134 and the reaction zone 164.

However, the gas distribution faceplate 125 tends to choke the flow of the cleaning gas to the pumping liner 179 and prolongs the cleaning process. A pump 200 is provided to pump gas through the pumping liner 179 on the side opposite the slit valve 108. An exhaust system 180 having an exhaust conduit 184 coupled to the isolation collar 192 at a first end 186 and to the pumping liner 179 at a second end 188. A valve 182 connected to exhaust conduit 184 is configured to selectively establish fluid coupling of the exhaust conduit 184 to the inner channel 193. In some embodiments, for example, the valve 182 may be a plunger type valve having a plunger that is moveable between a first to fluidly couple the exhaust conduit 184 to the inner channel 193 and a second position to seal off the exhaust conduit 184 from the inner channel 193. Each time the cleaning gas is flowed through the inner gas channel 134 and the reaction zone 164, the valve 182 is opened and the cleaning gas is rapidly exhausted to the pumping liner 179.

When a pressure inside of the substrate processing chamber 100 exceeds a pressure inside of the RPS 190, processing gasses may flow up to and damage the RPS 190. The plurality of cap openings 139 are configured to provide a choke point to prevent a backflow of processing gases from flowing up through the inner channel 193 and into the RPS 190. The isolation collar 192 may be formed of any material that is non-reactive with the cleaning gas being used. In some embodiments, the isolation collar 192 may be formed of aluminum when the cleaning gas is NF₃. In some embodiments, the isolation collar 192 and the gas insert 133 may be formed of aluminum and coated with a coating to prevent corrosion of the isolation collar 192 and the gas insert 133 from corrosive gases when used. For example, the coating may be formed of nickel or aluminum oxide.

In a substrate processing operation during a CVD or ALD process, a substrate 110 is delivered to the substrate processing chamber 100 through slit valve 108 by a robot (not shown). The substrate 110 is positioned on pedestal 112 through cooperation of lift pins (not shown) and the robot. The pedestal 112 raises substrate 110 into close opposition to a lower surface of the gas distribution faceplate 125. A first gas flow may be injected into inner gas channel 134 of the substrate processing chamber 100 by the gas delivery system 130 together or separately (i.e., pulses) with a second gas flow. The first gas flow may contain a continuous flow of a purge gas from a purge gas source and pulses of a reactant gas from a reactant gas source or may contain pulses of a reactant gas from the reactant gas source and pulses of a purge gas from the purge gas source. The second gas flow may contain a continuous flow of a purge gas from a purge gas source and pulses of a reactant gas from a reactant gas source or may contain pulses of a reactant gas from a reactant gas source and pulses of a purge gas from a purge gas source.

The gas flow travels through inner gas channel 134 and is then deposited on the surface of the substrate 110. The bottom surface 160 of chamber lid assembly 132, which is downwardly sloping, is configured to reduce the variation of the velocity of the gas flow across the surface of gas distribution faceplate 125. Excess gas, by-products, etc. flow into the pumping liner 179 and are then exhausted from the substrate processing chamber 100. Throughout the processing operation, the heater plate circumferentially surrounding the gas manifold 131 may heat the chamber lid assembly 132 to a predetermined temperature to heat any solid byproducts that have accumulated on walls of the substrate processing chamber 100 (or a processing kit disposed in the chamber). As a result, any accumulated solid byproducts are vaporized. The vaporized byproducts are evacuated by a vacuum system (not shown) and pumping liner 179. In some embodiments, the predetermined temperature is greater than or equal to 150° C.

One or more embodiments of the substrate processing chamber edge ring is configured to provide circumferential variation in conductance by an angled profile on the edge ring top surface through the pumping liner during CVD or ALD processes performed in substrate processing chambers that utilize the substrate processing chamber edge ring according to one or more embodiments. This, in turn, provides a narrower flow path and higher flow resistance at the pumping side. The flow resistance reduces towards the slit valve side in a gradual and continuous manner. The variable conductance thus achieved redistributes the flow and improves flow uniformity in the process cavity and around the substrate.

During CVD and ALD processes, uniform gas flow conductance through the pumping liner in the substrate processing chamber is needed to distribute the precursor uniformly across the substrate surface and to form uniform thin films. Non-uniform gas flow conductance through the pumping liner results in non-uniform film thickness across the substrate

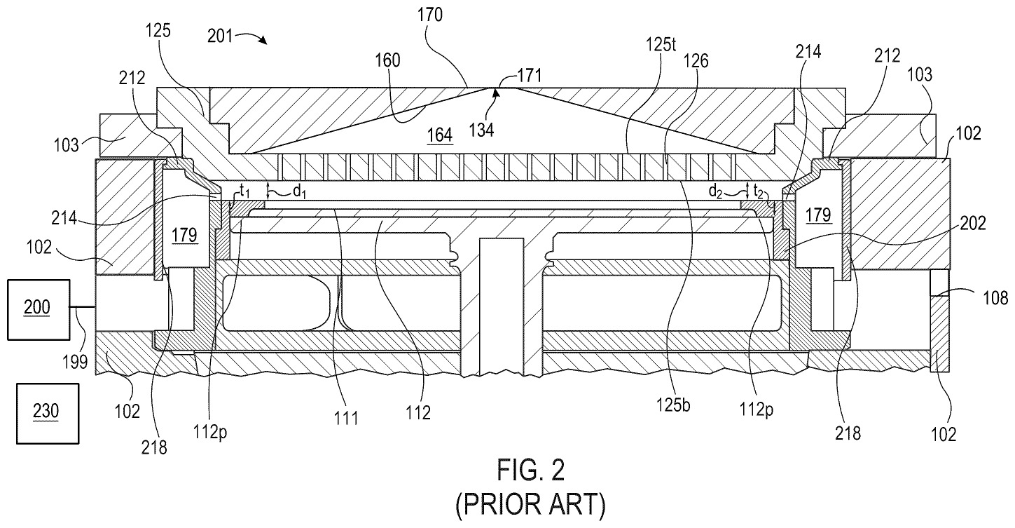

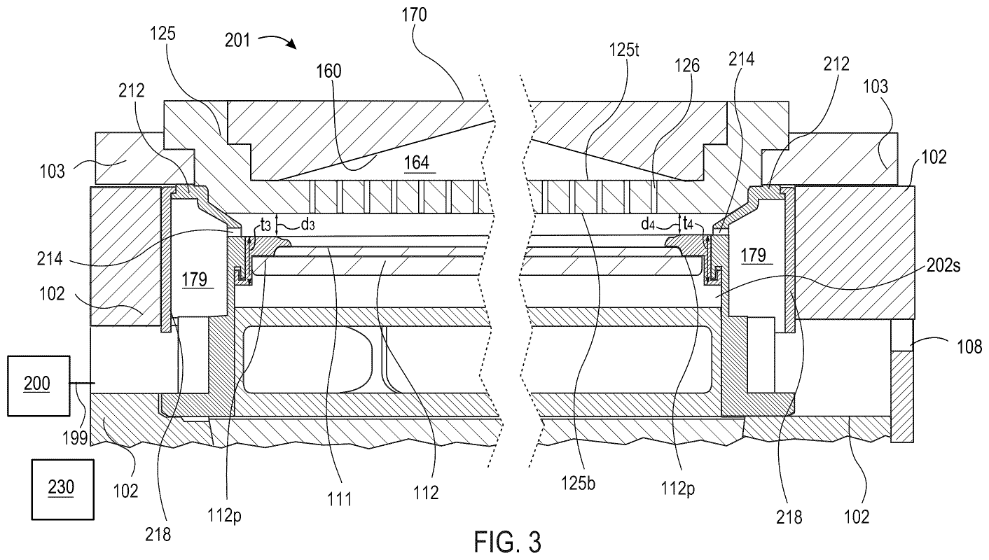

A first aspect of the disclosure pertains to a substrate processing chamber 100 including a substrate processing chamber gas distribution assembly 201 shown in FIG. 2 and FIG. 3. All of the components of substrate processing chamber 100 and the substrate processing chamber gas distribution assembly 101 shown in FIG. 1 are not repeated in FIG. 2 and FIG. 3. For example, in the embodiments shown in FIG. 2 and FIG. 3, the gas distribution assembly includes the chamber lid assembly 132, the gas manifold 131, the gas delivery system 130 and the gas distribution faceplate 125 as shown in FIG. 1. However, the present disclosure is not limited to the chamber lid assembly 132, the gas manifold 131, the gas delivery system 130, and the gas distribution faceplate 125 arrangement as shown in FIG. 1.

FIG. 2 and FIG. 3 show a portion of a substrate processing chamber to highlight the features that are configured to provide variable gas flow conductance through the pumping liner 179. The gas distribution faceplate 125 has a top surface 125t and a bottom surface 125b. The substrate processing chamber gas distribution assembly 201 shown in FIG. 2 includes a substrate processing chamber edge ring 202 that has a thickness t₁ on a first side and a thickness t₂ on a second side of substrate processing chamber edge ring 202 that are equal. Since t₁=t₂, the distance d₁ from the edge ring top surface 202t to the gas distribution bottom plate bottom surface 125b on the side of the chamber adjacent to the pump is equal to the distance d₂ from the edge ring top surface on the side or end of the chamber closest to the slit valve.

In FIG. 2 and FIG. 3 the substrate processing chamber comprises the substrate processing chamber gas distribution assembly 201 having the backing plate 170 coupled to the gas manifold 131, and the backing plate 170 has a contoured bottom surface 160 that extends downwardly and outwardly from a central opening 171 coupled to the lower portion of the inner gas channel to a peripheral portion 170p of the backing plate 170. As shown in both FIG. 2 and FIG. 3, a gas distribution faceplate 125 is disposed below the backing plate170, having a top surface 125t and a bottom surface 125b.

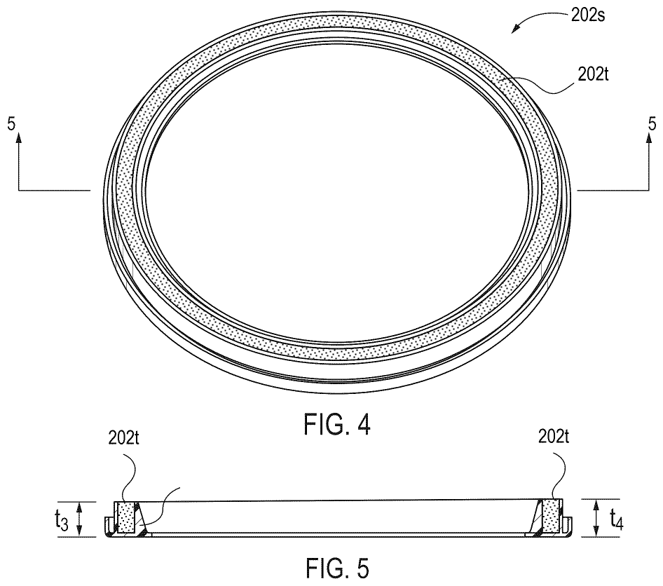

The features according to one or more embodiments of the disclosure that are configured to adjustment of gas flow conductance will now be described with respect to FIGS. 3-5. A sloped edge ring 202s is supported on a pedestal 112 disposed beneath the gas distribution faceplate 125 and configured to support a substrate 110 (not shown in FIG. 2). The pedestal 112 has an outer peripheral portion 112p, and the substrate processing chamber edge ring 202s is disposed on the outer peripheral portion 112p of the pedestal 112.

The substrate processing chamber edge ring 202s in FIG. 3 has first edge ring thickness at a first edge t₃ and a thickness t₄ on a second side of substrate processing chamber edge ring 202s such that the thickness t₃ is greater than a thickness t₄ at a second edge opposite the first edge. This difference in thickness t₃ of the substrate processing chamber edge ring 202s being greater on one side than the thickness t₄ on the second side results in a distance d₃ from the edge ring top surface 202t to the gas distribution bottom plate bottom surface 125b on the side of the chamber adjacent to the pump being less than the distance d₄ from the edge ring top surface 202t on the side or end of the chamber closest to the slit valve when placed in a substrate processing chamber as shown in FIG. 3.

Thus, embodiments of the disclosure provide a substrate processing chamber edge ring 202s configured for use in vapor deposition process comprising a ring-shaped body having a lower surface configured to be supported on a substrate processing chamber pedestal and an upper surface, the lower surface and the upper surface defining an edge ring thickness, the substrate processing chamber edge ring having a first edge ring thickness t₃ at a first edge of the ring-shaped body that is greater than a second edge ring thickness at a second edge opposite the first edge of the substrate processing chamber edge ring. Thus, the ring-shaped body tapers from the first edge ring thickness t₃ to the second edge ring thickness t₄ to provide a sloped surface. This results in the substrate processing chamber edge ring 202s having a wedge-shaped profile. In some embodiments, the wedge-shaped profile has a slope in a range of from 0.15 degrees to about 0.45 degrees. In other embodiments, the wedge-shaped profile has a slope in a range of from 0.20 degrees to about 0.40 degrees.

Other embodiments pertain to a substrate processing chamber gas distribution assembly 201 comprises the substrate processing chamber edge ring 202s described herein and the gas distribution faceplate 125 having a top surface 125t and a bottom surface 125b, wherein the gas distribution faceplate is disposed above the substrate processing chamber edge ring 202s and wedge-shaped profile of the substrate processing chamber edge ring 202s provides a gap between the substrate processing chamber edge ring and the bottom surface of the gas distribution first plate that tapers from a first end of the gas distribution faceplate to a second end of the gas distribution faceplate such that the gap is larger on the first end than on the second end of the gas distribution faceplate. In some embodiments, the substrate processing chamber gas distribution assembly 201 further comprises a pumping liner 179 surrounding the substrate processing chamber edge ring.

In some embodiments, the substrate processing chamber gas distribution assembly 201 further comprises a pump 200 in flow communication with the pumping liner 179 adjacent the first edge of the substrate processing chamber edge ring and a slit valve 108 adjacent the second edge of the substrate processing chamber edge ring 202s. Advantageously, the wedge-shaped profile of the substrate processing chamber edge ring 202s provides a circumferentially varying flow conductance during a vapor deposition process.

Another aspect pertains to a substrate processing chamber 100 configured for a vapor deposition process and comprising the substrate processing chamber gas distribution assembly 201 described herein and further comprising a pedestal 112 configured to support a substrate during a vapor deposition process. In embodiments, the circumferentially varying flow conductance provides increased gas flow uniformity on a substrate during a vapor deposition process.

Another aspect pertains to a method of forming a film on a substrate in substrate processing chamber, the method comprising establishing a gas flow between a sloped edge ring surrounding a pedestal configured to support the substrate during a vapor deposition process, the substrate processing chamber edge ring having sloped profile configured to provide a sloped gap between the substrate processing chamber edge ring and a gas distribution faceplate disposed above the substrate processing chamber edge ring, wherein the sloped gap is less on a first end of the substrate processing chamber than on a second end of substrate processing chamber. In some embodiments of the method, the substrate processing chamber edge ring is surrounded by a pumping liner including a pump in flow communication with the pumping liner on the first end of the substrate processing chamber and a slit valve on the second end of processing chamber in flow communication with the pumping liner.

In some embodiments of the method, the gap on the first end is in a range of 50 to 100 mils and the gap on the second end is in a range of 120-180 mils. In some embodiments of the method the slope is in a range of from 0.15 degrees to about 0.45 degrees. In specific embodiments of the method, the slope is in a range of from 0.20 degrees to 0.40 degrees. In some embodiments, the sloped gap minimizes gas flow non-uniformity on the substrate during a vapor deposition process. The method of some embodiments further comprises pumping gas flow in a direction from the second end to the first end of the substrate processing chamber.

Advantageously, the variable conductance edge ring according to one or more embodiments provides a narrower flow path which is achieved by using an angled top edge ring profile with a gradual slope from pumping end (maximum thickness) to slit valve end (minimum thickness). The angled top edge ring profile results in a variable gap circumferentially between the edge ring top surface and the showerhead bottom surface, providing a minimum gap and lower gas flow conductance at the pumping end of the semiconductor substrate processing chamber and a maximum gap and higher gas flow conductance at the slit valve end of the semiconductor substrate processing chamber. This thus provides a narrower flow path and higher flow resistance at the pumping side of the semiconductor substrate processing chamber during a vapor deposition process such a CVD or ALD process used to deposit a thin film on a substrate. The flow resistance reduces towards the slit valve side of the semiconductor substrate processing chamber in a gradual and continuous manner. The variable conductance thus achieved redistributes the flow and improves flow uniformity in the process cavity and around the substrate in the semiconductor substrate processing chamber.

The modified edge ring according to one or more embodiments modifies the edge ring top surface to provide an angular/slanted profile)and involves minimal design modifications and manufacturing changes. This also results in minor changes to edge ring surface area, and hence the purging and loading time remains mostly unchanged compared to conventional designs. Advantageously, the variable conductance edge ring provides a gradually varying flow resistance from pumping side to slit valve side of the substrate processing chamber and ensures better flow uniformity inside the process chamber and around the substrate during processing.

Although the disclosure herein provided a description with reference to particular embodiments, it is to be understood that these embodiments are merely illustrative of the principles and applications of the disclosure. It will be apparent to those skilled in the art that various modifications and variations can be made to the present disclosure without departing from the spirit and scope thereof. Thus, it is intended that the pre-sent disclosure include modifications and variations that are within the scope of the appended claims and their equivalents.

What is claimed is:

1. A substrate processing chamber edge ring comprising:
a ring-shaped body having a lower surface configured to be supported on a substrate processing chamber pedestal and an upper surface, the lower surface and the upper surface defining an edge ring thickness, the substrate processing chamber edge ring having a first edge ring thickness at a first edge of the ring-shaped body that is greater than a second edge ring thickness at a second edge opposite the first edge of the substrate processing chamber edge ring.

2. The substrate processing chamber edge ring of claim 1, wherein the ring-shaped body tapers from the first edge ring thickness to the second edge ring thickness.

3. The substrate processing chamber edge ring of claim 2, wherein the substrate processing chamber edge ring has a wedge-shaped profile.

4. The substrate processing chamber edge ring of claim 3, wherein the wedge-shaped profile has a slope in a range of from 0.15 degrees to about 0.45 degrees.

5. The substrate processing chamber edge ring of claim 4, wherein the wedge-shaped profile has a slope in a range of from 0.20 degrees to about 0.40 degrees.

6. A substrate processing chamber gas distribution assembly comprising:
the substrate processing chamber edge ring according to claim 3; and
a gas distribution faceplate having a top surface and a bottom surface, wherein the gas distribution faceplate is disposed above the substrate processing chamber edge ring and wedge-shaped profile of the substrate processing chamber edge ring provides a gap between the substrate processing chamber edge ring and the bottom surface of the gas distribution faceplate that tapers from a first end of the gas distribution faceplate to a second end of the gas distribution faceplate such that the gap is larger on the first end than on the second end of the gas distribution faceplate.

7. The substrate processing chamber gas distribution assembly of claim 6, further comprising a pumping liner surrounding the substrate processing chamber edge ring.

8. The substrate processing chamber gas distribution assembly of claim 7, wherein further comprising a pump in flow communication with the pump liner adjacent the first edge of the substrate processing chamber edge ring and a slit valve adjacent the second edge of the substrate processing chamber edge ring.

9. The substrate processing chamber gas distribution assembly of claim 8, wherein the wedge-shaped profile of the substrate processing chamber edge ring provides a circumferentially varying flow conductance during a vapor deposition process.

10. A vapor deposition chamber comprising the substrate processing chamber gas distribution assembly of claim 9 and further comprising a pedestal configured to support a substrate during a vapor deposition process.

11. The vapor deposition chamber of claim 10, wherein the circumferentially varying flow conductance provides increased gas flow uniformity on a substrate during a vapor deposition process.

12. A method of forming a film on a substrate in substrate processing chamber, the method comprising establishing a gas flow between a sloped substrate processing chamber edge ring surrounding a pedestal configured to support the substrate during a vapor deposition process, the sloped substrate processing chamber edge ring having sloped profile configured to provide a sloped gap between the substrate processing chamber edge ring and a gas distribution faceplate disposed above the substrate processing chamber edge ring, wherein the sloped gap is less on a first end of the substrate processing chamber than on a second end of substrate processing chamber.

13. The method of claim 12, wherein the substrate processing chamber edge ring is surrounded by a pumping liner including a pump in flow communication with the pumping liner on the first end of the substrate processing chamber and a slit valve on the second end of processing chamber in flow communication with the pumping liner.

14. The method of claim 13, wherein the gap on the first end is in a range of 50 to 100 mils and the gap on the second end is in a range of 120-180 mils.

15. The method of claim 14, wherein the slope is in a range of from 0.15 degrees to about 0.45 degrees.

16. The method of claim 14, wherein the slope is in a range of from 0.20 degrees to 0.40 degrees.

17. The method of claim 14, wherein the sloped gap increases gas flow uniformity on the substrate during a vapor deposition process.

18. The method of claim 17, further comprising pumping gas flow in a direction from the second end to the first end of the substrate processing chamber.
